(19) United States
(12) Patent Application Publication
(10) Pub. No.: US 2019/0096461 A1
(43) Pub. Date: Mar. 28, 2019

(54) MEMORY DEVICE

(71) Applicant: Toshiba Memory Corporation, Minato-ku (JP)

(72) Inventors: Masahiro Koike, Tokyo (JP); Shogo Itai, Kawasaki (JP); Tadaomi Daibou, Yokohama (JP); Chikayoshi Kamata, Kawasaki (JP); Junichi Ito, Yokohama (JP); Masahiko Nakayama, Kawasaki (JP)

(73) Assignee: Toshiba Memory Corporation, Minato-ku (JP)

(21) Appl. No.: 15/916,721

(22) Filed: Mar. 9, 2018

(30) Foreign Application Priority Data
Sep. 22, 2017 (JP) 2017-181967

(51) Int. Cl. G11C 11/16; H01L 43/02; H01L 43/08

(52) U.S. Cl. CPC G11C 11/161; G11C 11/1673; H01L 43/08; H01L 43/02; G11C 11/1675

(57) ABSTRACT

According to one embodiment, a memory device includes: a first memory element arranged above a substrate; a first contact portion adjacent to the first memory element in a first direction parallel to a surface of the substrate; a second contact portion arranged above the first memory element in a second direction perpendicular to the surface of the substrate; and a second memory element arranged above the first contact portion in the second direction. First dimensions at upper parts of the first and second memory elements are smaller than second dimensions at lower parts of the first and second memory elements, and third dimensions at upper parts of the first and second contact portions are larger than fourth dimensions at lower parts of the first and second contact portions.

### CROSS-REFERENCE TO RELATED APPLICATIONS

This application is based upon and claims the benefit of priority from Japanese Patent Application No. 2017-181967, filed Sep. 22, 2017, the entire contents of which are incorporated herein by reference.

### FIELD

Embodiments described herein relate generally to a memory device.

### BACKGROUND

Development and research have been conducted on novel structures and manufacturing methods of memory devices for the sake of reducing bit costs and improving storage density of the memory devices.

### BRIEF DESCRIPTION OF THE DRAWINGS

FIG. 1 is a block diagram showing a configuration example of a system including a memory device according to an embodiment.

FIG. 2 is a block diagram showing a configuration example of the memory device according to the embodiment.

FIG. 3 is an equivalent circuit diagram showing a configuration example of a memory cell array of the memory device according to the embodiment.

FIG. 4 is a cross-sectional view showing a configuration example of a memory element of the memory device according to the embodiment.

FIG. 5 is a plane view showing a configuration example of a memory device according to a first embodiment.

FIG. 6 and FIG. 7 are cross-sectional views showing a configuration example of the memory device according to the first embodiment.

FIG. 8 to FIG. 21 show one step of a method of manufacturing the memory device according to the first embodiment.

FIG. 22 is a plane view showing a configuration example of a memory device according to a second embodiment.

FIG. 23 is a cross-sectional view showing a configuration example of the memory device according to the second embodiment.

FIG. 24 is a plane view showing a configuration example of a memory device according to a third embodiment.

FIG. 25 and FIG. 26 are cross-sectional views showing a configuration example of the memory device according to the third embodiment.

FIG. 27 is a cross-sectional view showing a configuration example of a memory device according to a fourth embodiment.

FIG. 28 to FIG. 31 show one step of a method of manufacturing the memory device according to the fourth embodiment.

FIG. 32 is a cross-sectional view showing a configuration example of a memory device according to a fifth embodiment.

FIG. 33 and FIG. 34 show one step of a method of manufacturing the memory device according to the fifth embodiment.

FIG. 35 to FIG. 38 show one step of a method of manufacturing a memory device according to a sixth embodiment.

FIG. 39 shows a modification of the memory device of the embodiment.

### DETAILED DESCRIPTION

In general, according to one embodiment, a memory device includes: a first memory element arranged above a substrate; a first contact portion adjacent to the first memory element in a first direction parallel to a surface of the substrate; a second contact portion arranged above the first memory element in a second direction perpendicular to the surface of the substrate; and a second memory element arranged above the first contact portion in the second direction. First dimensions at upper parts of the first and second memory elements are smaller than second dimensions at lower parts of the first and second memory elements, and third dimensions at upper parts of the first and second contact portions are larger than fourth dimensions at lower parts of the first and second contact portions.

### Embodiment

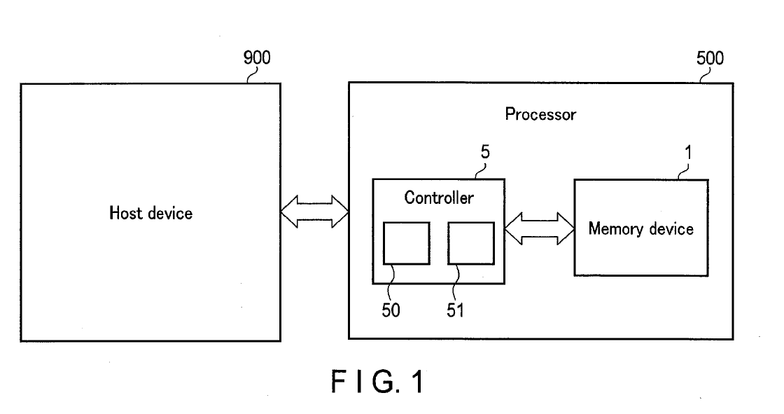

A memory device and a method of manufacturing the memory device according to an embodiment will be explained with reference to FIG. 1 to FIG. 39.

In the following, the present embodiment will be explained in detail with reference to the accompanying drawings. In the description below, elements having the same functions and configurations will be denoted by the same reference symbols.

In addition, in the following embodiments, when elements have reference symbols with numbers or English letters provided at the end for distinction (for example, a word line WL, a bit line BL, various voltages and signals, and the like) but are not necessarily distinguished from each other, a description will be made (with the reference symbols) without the numbers or English letters at the end.

### (1) First Embodiment

A memory device and a method of manufacturing the memory device according to a first embodiment will be explained with reference to FIG. 1 to FIG. 21.

(a) Configuration

A configuration of the memory device according to the present embodiment will be explained with reference to FIG. 1 to FIG. 4.

FIG. 1 is a block diagram showing an example of a system including the memory device according to the present embodiment.

As illustrated in FIG. 1, the memory system includes, for example, a memory device 1 according to the present embodiment, a memory controller 5, and a host device 900.

The host device 900 can make a request to the memory device 1 via the memory controller 5 for various operations such as writing (storing) data, reading data, and erasing data.

The memory device 1 is directly or indirectly connected to the memory controller 5. The memory device 1 is, for example, a storage-class memory and a main memory.

The memory controller 5 is directly or indirectly coupled to the host device 900 via a connection terminal, a connector, or a cable.

The memory controller 5 controls operation of the memory device 1. The memory controller 5 includes a processing circuit 50, a built-in memory 51, an ECC circuit, and the like.

The memory controller 5 issues a command based on a request from the host device 900. The memory controller 5 sends the issued command to the memory device 1.

The memory device 1 performs an operation corresponding to the command from the memory controller 5.

When the request from the host device 900 is to write data, for example, the memory controller 5 sends a write command to the memory device 1. The memory controller 5 sends, along with the write command, an address of a memory cell to be selected, data to be written in the memory cell, and a control signal. The memory device 1 writes data to be written in the selected address based on the write command and the control signal.

When the request from the host device 900 is to read data, for example, the memory controller 5 sends a read command to the memory device 1. The memory controller 5 sends, along with the read command, an address of a memory cell to be selected, and a control signal. The memory device 1 reads data from the selected address based on the read command and the control signal. The memory device 1 sends the read data to the memory controller 5. The memory controller 5 receives data from the memory device 1. The memory controller 5 sends the data from the memory device 1 to the host device 900.

In this manner, the memory device 1 performs predetermined operations in the memory system by control from other device 900, 5.

The memory device 1 and the memory controller 5 are, for example, provided in a processor 500. The host device 900 is electrically coupled to the processor 500. The host device 900 is at least one device selected from a mobile terminal, smartphone, game machine, processor, server, personal computer, and the like.

In the following, at least one of the memory controller 5 and the host device 900 is referred to as an external device.

The memory device 1 according to the present embodiment may be a memory in the memory controller 5 or in the host device 900. In addition, the memory controller 5 may be provided in the host device 900. The processor 500 may be provided in the host device 900.

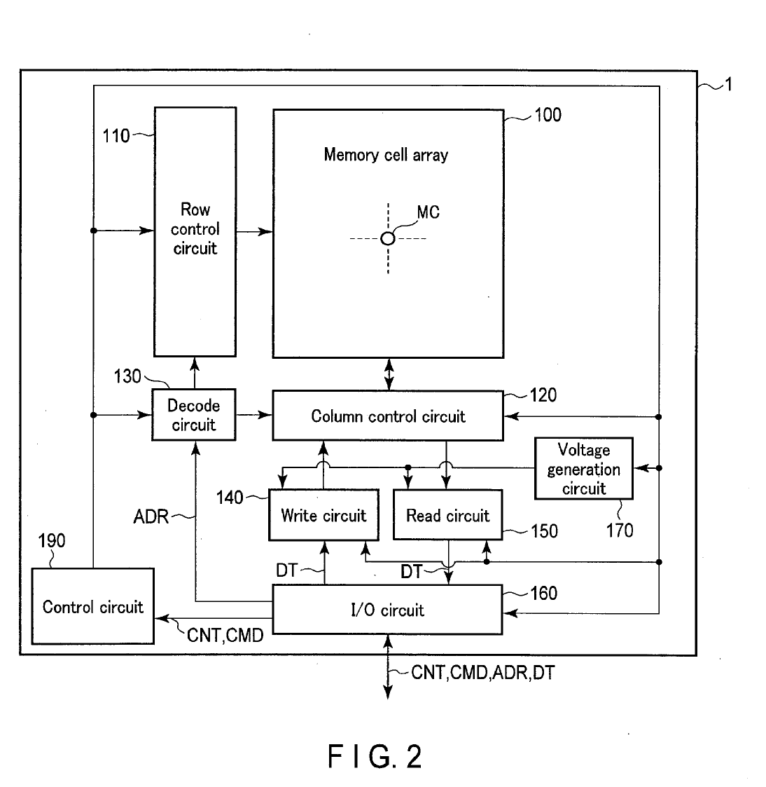

FIG. 2 is a block diagram showing an internal configuration of the memory device according to the present embodiment.

As illustrated in FIG. 2, the memory device 1 according to the present embodiment includes a memory cell array 100, a row control circuit 110, a column control circuit 120, a decode circuit 130, a write circuit 140, a read circuit 150, an I/O circuit 160, a voltage generation circuit 170, a control circuit 190, and the like.

The memory cell array 100 includes a plurality of memory cells MC.

The row control circuit 110 controls a plurality of rows of the memory cell array 100. A decode result of an address (row address) from the decode circuit 130 is supplied to the row control circuit 110. The row control circuit 110 sets a row (for example, a word line) in a selected state based on the decode result of the address. In the following, row (word line) that have been set in the selected state is referred to as a selected row (selected word line). Row other than the selected row is referred to as a non-selected row (non-selected word lines).

The column control circuit 120 controls a plurality of columns of the memory cell array 100. A decode result of an address (column address) from the decode circuit 130 is supplied to the column control circuit 120. The column control circuit 120 sets a column (for example, at least one bit line) in a selected state based on the decode result of the address. In the following, the column (bit line) that have been set in a selected state is referred to as a selected column (selected bit line). Column other than the selected column is referred to as non-selected column (non-selected bit line).

The decode circuit 130 decodes an address ADR from the I/O circuit 160. The decode circuit 130 supplies a decode result of the address ADR to the row control circuit 110 and the column control circuit 120. The address (for example, physical address) ADR includes a column address to be selected and a row address to be selected.

The write circuit (also referred to as a write control circuit or a write driver) 140 performs various controls for write operations (data writing). The write circuits 140 supplies a write current to a memory cell array 100 during the write operation to thereby write data in the memory element.

The write circuit 140 includes, for example, a voltage source (or a current source), a latch circuit, and the like.

The read circuit (also referred to as a read control circuit or a read driver) 150 performs various controls for read operations (data reading). The read circuit 150 senses a potential of the bit line BL or a current value during the read operation to thereby read data in the memory element.

The read circuit 150 includes, for example, a voltage source (or a current source), a latch circuit, a sense amplifier circuit, and the like.

The write circuit 140 and the read circuit 150 are not limited to circuits independent from each other. The write circuit and the read circuit may include, for example, common structural elements available to each other and may be provided as a single comprehensive circuit.

The I/O circuit (input/output circuit) 160 is an interface circuit for transmitting and receiving various signals in the memory device 1.

During the write operation, the I/O circuit 160 transfers, to the write circuit 140, data DT from the external device (for example, the memory controller 5) as write data. During the read operation, the I/O circuit 160 transfers, to the external device, data DT output from the memory cell array 100 to the read circuit 150 as read data.

The I/O circuit 160 transfers the address ADR from the external device to the decode circuit 130. The I/O circuit 160 transfers a command CMD from the external device to the control circuit 190. The I/O circuit 160 transmits and receives various control signals CNT between the control circuit 190 and the external device.

The voltage generation circuit 170 uses a power supply voltage provided from the external device to generate voltages for various operations of the memory cell array 100. For example, at the time of the write operation, the voltage generation circuit 170 outputs various voltages generated for the write operation to the write circuit 140. At the time of the read operation, the voltage generation circuit 170 outputs various voltages generated for the read operation to the read circuit 150.

The control circuit (also referred to as a state machine, a sequencer, or an internal controller) 190 controls the operation of each circuit in the memory device 1 based on the control signal CNT and the command CMD.

The command CMD is, for example, a signal indicating the operation to be performed by the memory device 1. The control signal CNT is, for example, a signal for controlling an operation timing between the external device 5, 900, and the memory device 1, and an operation timing in the memory device.

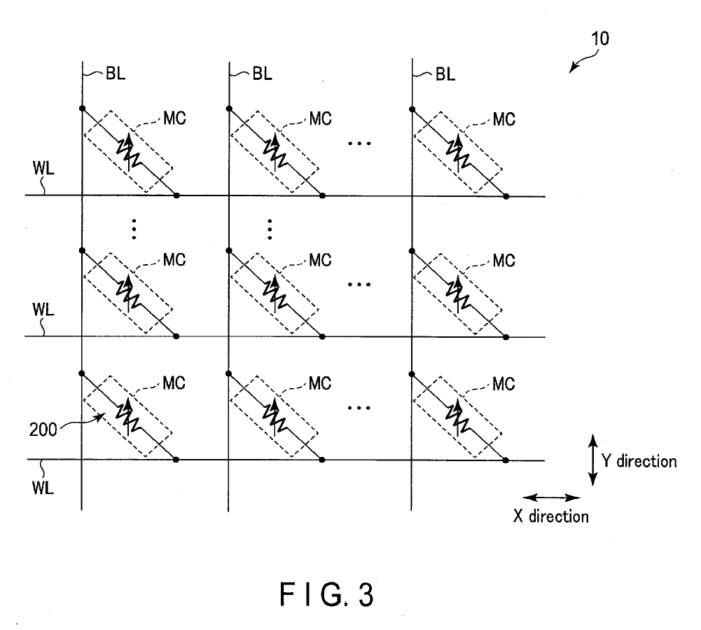

FIG. 3 is an equivalent circuit diagram showing an example of a configuration of the memory cell array of the memory device according to the present embodiment.

The memory device according to the present embodiment includes, for example, a memory cell array 100 having a cross-point structure.

As illustrated in FIG. 3, a plurality of word lines WL are arranged in the Y direction in the memory cell array 100. Each of the word lines WL extends in the X direction. A plurality of bit lines BL are arranged in the X direction in the memory cell array 100. Each of the bit lines BL extends in the Y direction.

A memory cell MC is arranged at an intersection where the bit line BL intersects with the word line WL. One end of the memory cell MC is connected to the bit line BL, and the other end of the memory cell MC is connected to the word line WL.

A plurality of memory cells MC arranged in the X direction are connected in common to one word line WL. A plurality of memory cells MC arranged in the Y direction are connected in common to one bit line BL.

For example, if the memory device according to the present embodiment is a magnetic memory (for example, an MRAM), one memory cell MC includes one magnetoresistive effect element 200. In an MRAM, the magnetoresistive effect element 200 functions as a memory element of the memory cell MC.

One end of the magnetoresistive effect element 200 is connected to the bit line BL, and the other end of the magnetoresistive effect element 200 is connected to the word line WL.

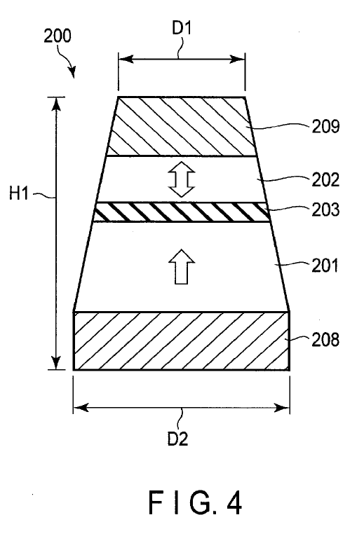

FIG. 4 is a schematic cross-sectional view showing the configuration of the magnetoresistive effect element in the memory cell of the memory device according to the present embodiment.

As illustrated in FIG. 4, the magnetoresistive effect element 200 includes at least two magnetic layers 201 and 202, and a nonmagnetic layer 203 between the two magnetic layers 201 and 202.

The magnetoresistive effect element 200 is a columnar stack.

The magnetic layers 201 and 202 and the nonmagnetic layer 203 form, for example, a magnetic tunnel junction. Therefore, the magnetoresistive effect element 200 has a magnetic tunnel junction. In the present embodiment, the magnetoresistive effect element 200 having magnetic tunnel junction is referred to as a MTJ element 200. The nonmagnetic layer 203 in the MTJ element is referred to as a tunnel barrier layer. The tunnel barrier layer 203 is an insulating film including MgO, for example.

An electrode 208 is provided at one end of the MTJ element 200. An electrode 209 is provided at the other end of the MTJ element 200. The magnetic layers 201 and 202 and the tunnel barrier layer 203 are located between the two electrodes 208 and 209.

In the following, one electrode 208 of the two electrodes is referred to as a lower electrode 208, and the other electrode 209 is referred to as an upper electrode 209, for the sake of clarification.

In the cross-sectional shape of the MTJ element 200, dimension D1 at the upper end side (upper electrode 209 side) of the MTJ element 200 is smaller than dimension D2 at the lower end side (lower electrode 208 side) of the MTJ element 200. Dimensions D1 and D2 are dimensions in a direction parallel to the surface of the substrate (for example, dimension in a diametrical or longitudinal direction).

The MTJ element 200 has dimension H1 in a direction perpendicular to the surface of the substrate.

In the following, a shape in which the dimension at the upper side of the element is smaller than the dimension at the lower side of the electrode is referred to as a taper shape. In contrast, a shape in which the dimension at the upper side of the element is larger than the dimension at the lower side of the element is referred to as a reverse taper shape.

The MTJ element 200 has, for example, a circular, elliptical, or rectangular plane shape.

In the example of FIG. 4, the magnetic layers 201 and 202 have perpendicular magnetic anisotropy. The magnetization of the magnetic layers 201 and 202 having perpendicular magnetic anisotropy is substantially perpendicular to the layer surface. The magnetization of the magnetic layers 201 and 202 is substantially parallel to the stacking direction of the layers 201, 202, and 203.

The magnetic layers 201 and 202 may have in-plane magnetic anisotropy. The magnetization of the magnetic layers 201 and 202 having in-plane magnetic anisotropy is substantially parallel to the layer surface. The magnetization of the magnetic layers 201 and 202 is substantially perpendicular to the stacking direction of the layers 201, 202, and 203.

The magnetic layer 201 has a fixed direction of magnetization (a fixed state, a pinned state), and the magnetic layer 202 has a variable direction of magnetization.

In the present embodiment, the magnetic layer 202 having a variable direction of magnetization is referred to as a storage layer (or a free layer) 102, and the magnetic layer 201 having a fixed direction of magnetization is referred to as a reference layer (a fixed layer, or a pinned layer) 201.

Having a fixed direction of magnetization means that the direction of magnetization of the reference layer 201 is not inverted when a voltage or a current for inverting (switching, changing) the direction of magnetization of the storage layer 202 is supplied to the magnetoresistive effect element 200. A voltage value or a current value in which a direction of magnetization of a magnetic layer is inverted is referred to as a magnetization switching threshold value.

The magnetization switching threshold value of the reference layer 201 is set to a higher value than the magnetization switching threshold value of the storage layer 202. Therefore, even when a voltage or a current of a magnetization switching threshold value of the storage layer 202 is supplied to the magnetoresistive effect element 200 to invert the direction of magnetization of the storage layer 202, the direction of magnetization of the reference layer 201 is not inverted.

A shift cancelling layer may be provided between the reference layer 201 and the lower electrode 208. The shift cancelling layer and the reference layer 201 form, for example, a synthetic antiferromagnetic (SAF) structure.

A resistance value (magnetic resistance value) of the MTJ element 200 varies in accordance with a relative relationship (magnetization alignment) between the direction of magnetization of the storage layer 202 and the direction of magnetization of the reference layer 201.

When the direction of magnetization of the storage layer 202 is the same as the direction of magnetization of the reference layer 201 (when the magnetization arrangement of the MTJ element is in a parallel arrangement state), the MTJ element 200 has a first resistance value R1.

When the direction of magnetization of the storage layer 202 is opposite to the direction of magnetization of the reference layer 201 (when the magnetization arrangement of the MTJ element is in an anti-parallel arrangement state), the MTJ element 200 has a second resistance value R2. The second resistance value is higher than the first resistance value.

In the present embodiment, regarding the magnetization arrangement state of the MTJ element, the parallel arrangement state is indicated as a P state, and the anti-parallel arrangement state is indicated as an AP state.

Using the feature that the MTJ element 200 has different resistance values depending on magnetization arrangement states, data (information) is stored in the MTJ element 200. For example, the MTJ element having the first resistance value or the second resistance value stores 1 bit (“0” or “1”) data.

For example, when the resistance value of the MTJ element 200 is set to the first resistance value R1, the MTJ element (MTJ element in a P state (low-resistance state)) 200 stores first data (for example, “0” data). When the resistance value of the MTJ element 200 is set to the second resistance value R2, the MTJ element (MTJ element in an AP state (high-resistance state)) 200 stores second data (for example, “1” data).

The MTJ element 200 can store data of two or more bits by controlling the configuration of the element (for example, the number of storage layers) or magnetization of the magnetic layer.

In the following, mainly an example in which the MTJ element is used as a memory element will be explained, but a memory element other than an MTJ element may be used for a memory cell in the memory device according to the present embodiment.

For example, as the memory element 200, one selected from the following may be used: a variable resistance element using a transition metal oxide (for example, titanium oxide), a phase change element using a chalcogenide-series material (for example, GeSbTe), an element using a laminated film of a transition metal oxide and a semiconductor (for example, titanium oxide and amorphous silicon), and the like.

(b) Configuration Example

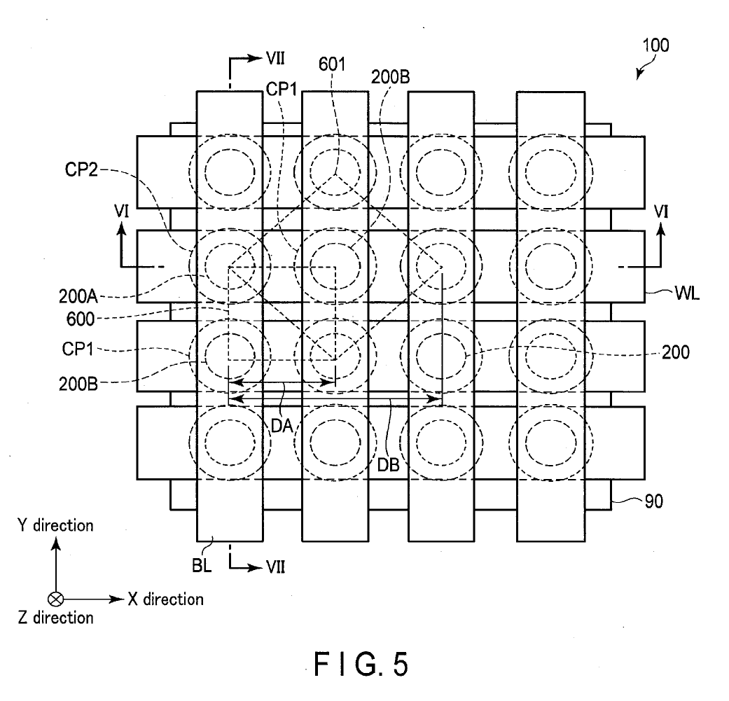

A configuration example of the memory device (for example, an MRAM) according to the present embodiment will be explained with reference to FIG. 5 to FIG. 7.

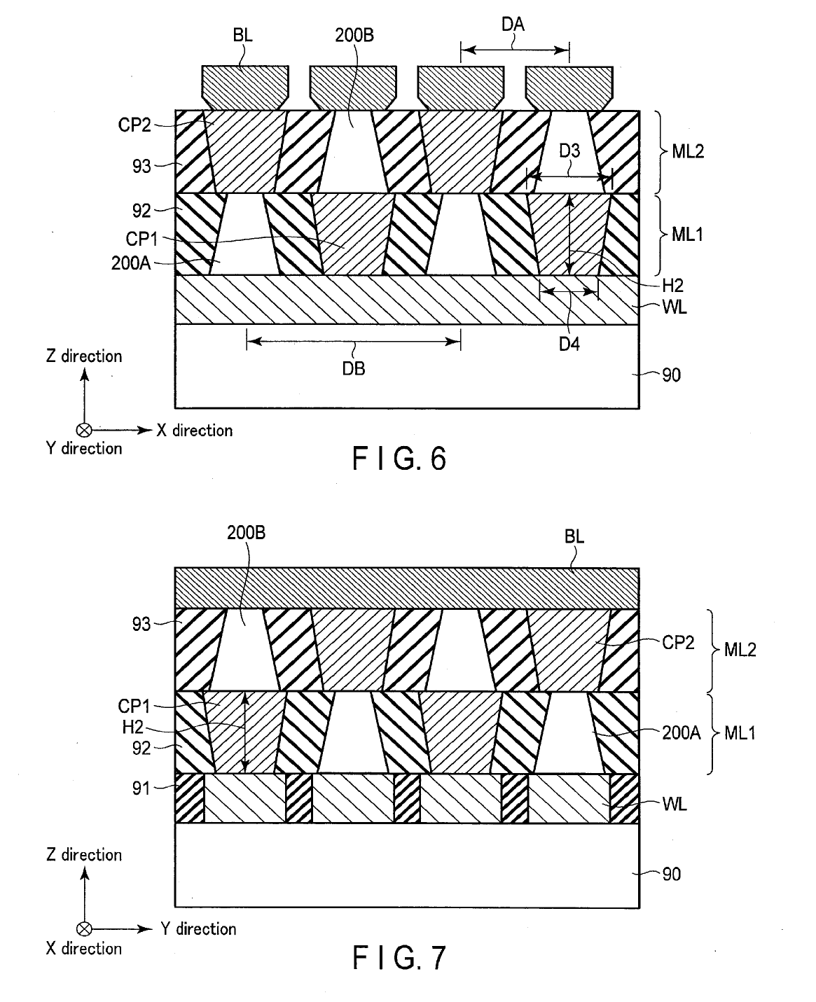

FIG. 5 is a plan view showing the configuration example of the memory cell array of the MRAM according to the present embodiment. FIG. 6 and FIG. 7 are cross-sectional views showing the configuration example of the memory cell array of the MRAM according to the present embodiment. FIG. 6 is a cross-sectional view taken along line VI-VI shown in FIG. 5. FIG. 7 is a cross-sectional view taken along line VII-VII shown in FIG. 5.

As illustrated in FIG. 5, a plurality of memory elements (MTJ elements here) 200 (200A, 200B) are arranged in a matrix pattern above a substrate 90 in an X-Y plane.

A plurality of word lines WL are arranged in the Y direction on the substrate 90. The word lines WL extend in the X direction. A plurality of bit lines BL are arranged in the X direction above the substrate 90. The bit lines BL extend in the Y direction.

In the present embodiment, the memory cell array 100 includes a plurality of layers (hereinafter referred to as array layers).

As illustrated in FIG. 6 and FIG. 7, the memory cell array 100 includes a first array layer (first layer) ML1 including a plurality of first MTJ elements 200A, and a second array layer (second layer) ML2 including a plurality of second MTJ elements 200B.

An interlayer insulating film 91 is provided between adjacent word lines WL in the Y direction.

The substrate 90 is, for example, an insulating film on a semiconductor substrate (for example, a silicon substrate). In this case, a plurality of elements (for example, transistors) to form the aforementioned circuit of the MRAM may be formed on the semiconductor substrate.

In the first array layer ML1, a plurality of MTJ elements 200A and a plurality of contact plugs (contact portions) CP1 are arranged in the X-Y plane. The MTJ elements 200A and the contact plugs CP1 are provided in an interlayer insulating film 92.

In the X direction, the plurality of MTJ elements 200A and the plurality of contact plugs CP1 are alternately arranged. In the Y direction, the plurality of MTJ elements 200A and the plurality of contact plugs CP1 are alternately arranged.

In the oblique direction in the X-Y plane, the plurality of MTJ elements 200A are arranged. In the oblique direction in the X-Y plane, the plurality of contact plugs CP1 are arranged.

The MTJ elements 200A and the contact plugs CP1 are arranged on the word line WL on the substrate 90.

In the MTJ element 200A in the first array layer ML1, in the Z direction, the lower electrode 208 of the MTJ element 200 shown in FIG. 4 is positioned on the word line WL side, and the upper electrode 209 of the MTJ element 200 is positioned on the bit line BL side.

In the cross-sectional shape of the contact plug CP1, dimension (length) D3 at the upper side (bit line BL side) of the contact plug CP1 is larger than dimension D4 at the lower side (word line WL side) of the contact plug CP1. For example, dimension D3 is equal to or larger than dimension D2. Dimension H2 of the contact plug CP1 in a direction perpendicular to the surface of the substrate is substantially the same as dimension H1. The contact plug CP1 has a reverse-tapered cross-sectional shape. The MTJ element 200A has a tapered cross-sectional shape.

The second array layer ML2 is stacked on the first array layer ML1 in the Z direction.

In the second array layer ML2, a plurality of MTJ elements 200B and a plurality of contact plugs CP2 are arranged in the X-Y plane. The MTJ elements 200B and the contact plugs CP2 are provided in the interlayer insulating film 93.

In the x direction, the plurality of MTJ elements 200B and the plurality of contact plugs CP2 are alternately arranged. In the Y direction, the plurality of MTJ elements 200B and the plurality of contact plugs CP2 are alternately arranged.

In the oblique direction in the X-Y plane, the plurality of MTJ elements 200B are arranged. In the oblique direction in the X-Y plane, the plurality of contact plugs CP2 are arranged.

The bit lines BL are arranged on the plurality of MTJ elements 200B and the plurality of contact plugs CP2 disposed in the Y direction.

In the MTJ element 200B in the second array layer ML2, in the Z direction, the lower electrode 208 of the MTJ element 200 shown in FIG. 4 is positioned on the word line WL side, and the upper electrode 209 of the MTJ element 200 is positioned on the bit line BL side.

Similar to the configuration of the contact plug CP1, in the cross-sectional shape of the contact plug CP2, the dimension (length) at the upper side of the contact plug CP2 is larger than the dimension at the lower side of the contact plug CP2. The dimension of the contact plug CP2 in the direction perpendicular to the surface of the substrate is dimension H2. The contact plug CP2 has a reverse-tapered cross-sectional shape. The MTJ element 200B has a tapered cross-sectional shape.

The MTJ element 200B is stacked on the contact plug CP1 in the Z direction. The contact plug CP2 is stacked on the MTJ element 200A in the Z direction.

In the Z direction, the MTJ element 200B is arranged so that the MTJ element 200B does not overlap with the MTJ element 200A in a vertical direction.

Therefore, when the memory cell array 100 is viewed in the Z direction, the memory cell array 100 has a layout in which the MTJ elements 200A and 200B of different array layers ML are arranged in a two-dimensional matrix pattern.

In the present embodiment, in each of the array layers ML, the tapered MTJ elements 200 and the reverse-tapered contact plugs CP are arranged in the array layer ML, and thus a density (filling rate) of the MTJ elements in the array layer ML can be improved.

In the memory cell array 100, the MTJ elements 200A and 200B are arranged at four corners of a 2×2 quadrangle 600 having sides parallel in the X direction and the Y direction. For example, MTJ elements 200 in the same array layer ML are arranged on the diagonal of the quadrangle. Consistent therewith, the contact plugs CP1 and CP2 overlapping with the MTJ elements 200 in the vertical direction are arranged at four corners of the 2×2 quadrangle. For example, contact plugs CP (CP1, CP2) in the same array layer ML are arranged on the diagonal of the quadrangle.

In a 2×2 quadrangle 601 having sides in oblique directions to the X direction and Y direction, MTJ elements 200 at four corners of the 2×2 quadrangle are MTJ elements in the same array layer ML. An MTJ element 200 arranged at the center of the quadrangle 601 is provided in a layer different from that having the MTJ elements 200 at the four corners of the quadrangle.

In the memory cell array 100, at four corners of a 3×3 quadrangle having parallel sides in the x direction and the Y direction, MTJ elements 200 in the same array layer ML are arranged. On the sides of the 3×3 quadrangle in the memory cell array 100, MTJ elements 200 in the layer different from the array layer of the four corners are arranged.

When the memory cell array 100 is viewed in the Z direction, a distance between the first MTJ element 200A and the second MTJ element 200B disposed in the X direction (or the Y direction) is indicated as “DA”. A distance between two MTJ elements 200 (200A, 200B) disposed in the X direction (or the Y direction) in the same array layer ML (ML1, ML2) is indicated as “DB”.

Distance DB is longer than distance DA.

In each of the array layers ML, the MTJ element 200 is provided between the contact plugs CP in the X direction and the Y direction. The MTJ element 200 is surrounded by the contact plugs CP in the X direction and the Y direction.

In the present embodiment, the configuration of a cross-point memory cell array is illustrated. The memory cell array of the MRAM according to the present embodiment may be configured so that a plurality of memory cells including transistors and MTJ elements are arranged.

The MRAM according to the present embodiment can perform data writing and data reading by the well-known write operation and read operation. Thus, an explanation of the write operation and the read operation will be omitted.

In the present embodiment, in each of the array layers ML, a large distance between MTJ elements 200 in the same array layer ML can be set. Therefore, a relatively large space for etching between the MTJ elements 200 at the time of forming each array layer is ensured.

Accordingly, in the present embodiment, difficulty in processing MTJ elements in each array layer ML can be lowered.

Furthermore, in the present embodiment, an influence of a stray magnetic field between MTJ elements can be suppressed.

In the memory device according to the present embodiment, because of the configuration in which the array layers including the tapered memory elements and the reverse-tapered contact plugs are stacked, it is possible to arrange the memory elements with high density in the memory cell array 100.

As a result, the memory device according to the present embodiment can realize high storage density.

(c) Manufacturing Method

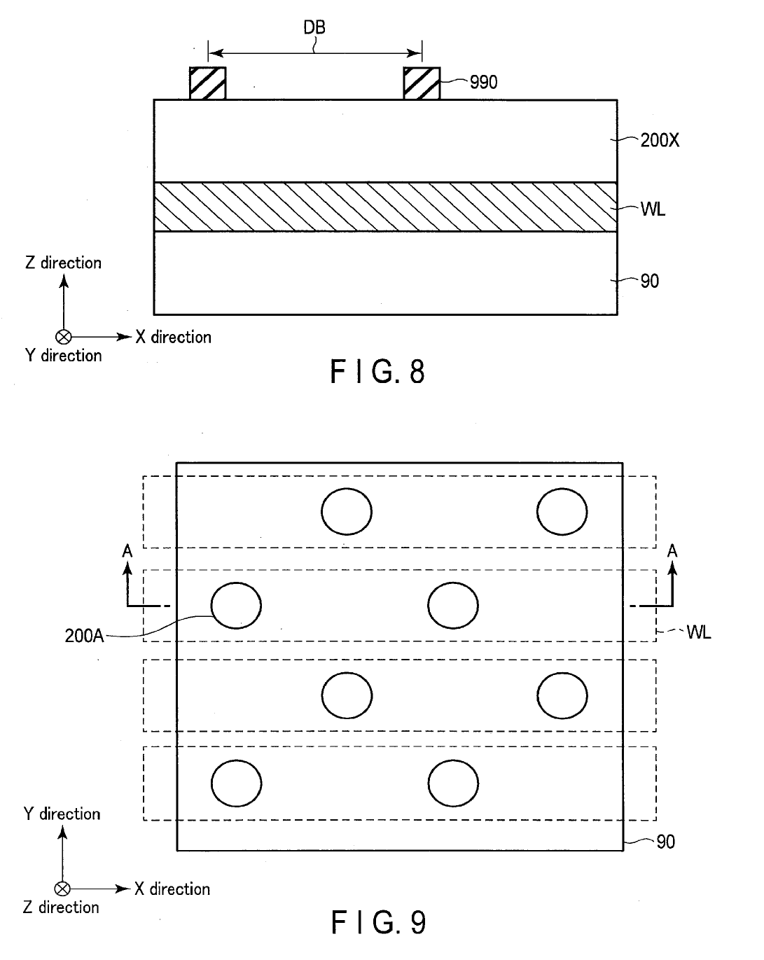

A method of manufacturing the memory device (for example, an MRAM) according to the present embodiment will be explained with reference to FIG. 8 to FIG. 21.

FIG. 8 is a cross-sectional view showing one step of the method of manufacturing the MRAM according to the present embodiment.

As illustrated in FIG. 8, a plurality of word lines WL are formed on the substrate 90 by a well-known film deposition technique, lithography technique, and etching technique.

A stack 200X is formed on the word line WL (and the insulating film between the word lines WL) by sputtering, a CVD process, and the like.

The stack 200X includes a plurality of layers (films) to form MTJ elements 200 of the first array layer. For example, the stack 200X includes layers (materials) to form, from the substrate 90 side, a lower electrode, a reference layer, a tunnel barrier layer, a storage layer, and an upper electrode.

On the stack 200X, a mask layer 990 is formed in a region where an MTJ element is formed (hereinafter referred to as an element formation region). An interval of distance DB is set between centers of mask layers 990 disposed in the X direction (or the Y direction).

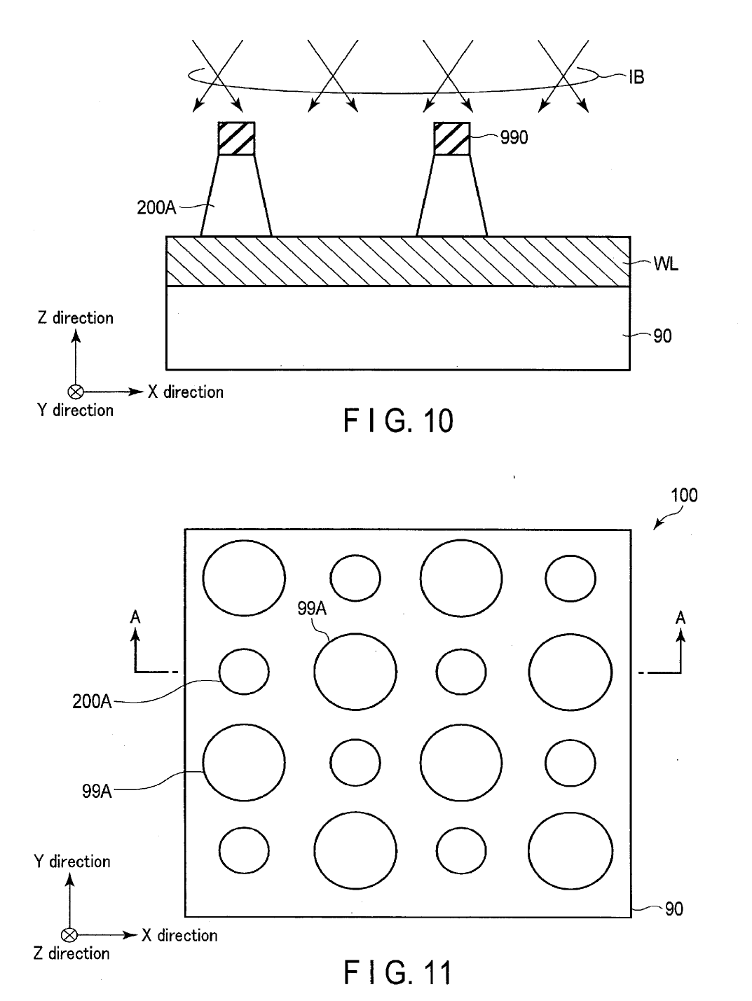

FIG. 9 is a plan view showing one step of the method of manufacturing the MRAM according to the present embodiment. FIG. 10 is a cross-sectional view taken along line A-A shown in FIG. 9 and showing one step of the method of manufacturing the MRAM according to the present embodiment.

As illustrated in FIG. 9 and FIG. 10, the stack is irradiated with ion beam IB from the direction oblique to the substrate 90 with the substrate 90 being rotated.

The tapered first MTJ element 200A is formed below the mask layer 990 and above the word line WL.

Since a relatively large space is ensured between two MTJ elements 200, ion beam etching from the direction oblique to the surface of the substrate 90 can be applied to the stack (MTJ elements) at a relatively large oblique angle. Accordingly, in the present embodiment, dispersant caused by etching is prevented from adhering to the MTJ elements 200A. As a result, generation of defective MTJ elements can be prevented in the present embodiment.

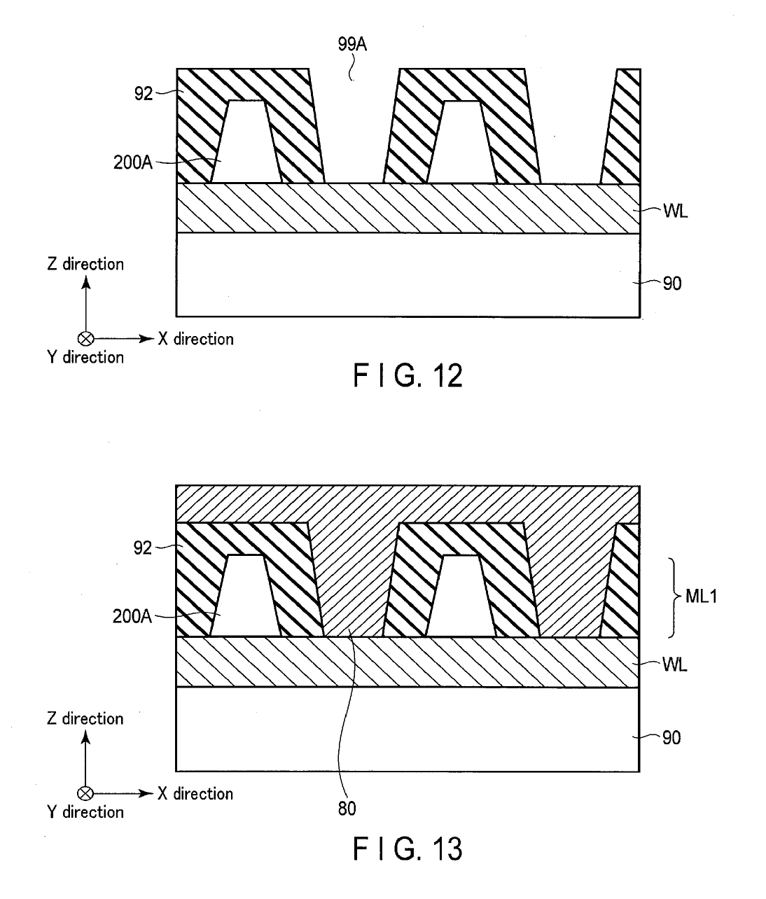

FIG. 11 is a plan view showing one step of the method of manufacturing the MRAM according to the present embodiment. FIG. 12 is a cross-sectional view taken along line A-A shown in FIG. 11 and showing one step of the method of manufacturing the MRAM according to the present embodiment.

As illustrated in FIG. 11 and FIG. 12, after the mask layer on the MTJ element 200A is removed, the interlayer insulating film 92 is formed on the MTJ element 200A and the word line WL by, for example, a CVD process in such a manner as to cover the MTJ element 200.

An insulating film (protecting film) may be formed on side surfaces of the MTJ element 200A before the interlayer insulating film 92 is formed.

In a region where the contact plug is to be formed, an opening (contact hole) 99A is formed in the interlayer insulating film 92 between MTJ elements 200A by the lithography technique and the etching technique.

FIG. 13 is a cross-sectional view showing one step of the method of manufacturing the MRAM according to the present embodiment.

As illustrated in FIG. 13, a conductor (for example, a metal) 80 is formed on the word line WL and the interlayer insulating film 92. The conductor 80 is filled in the formed opening.

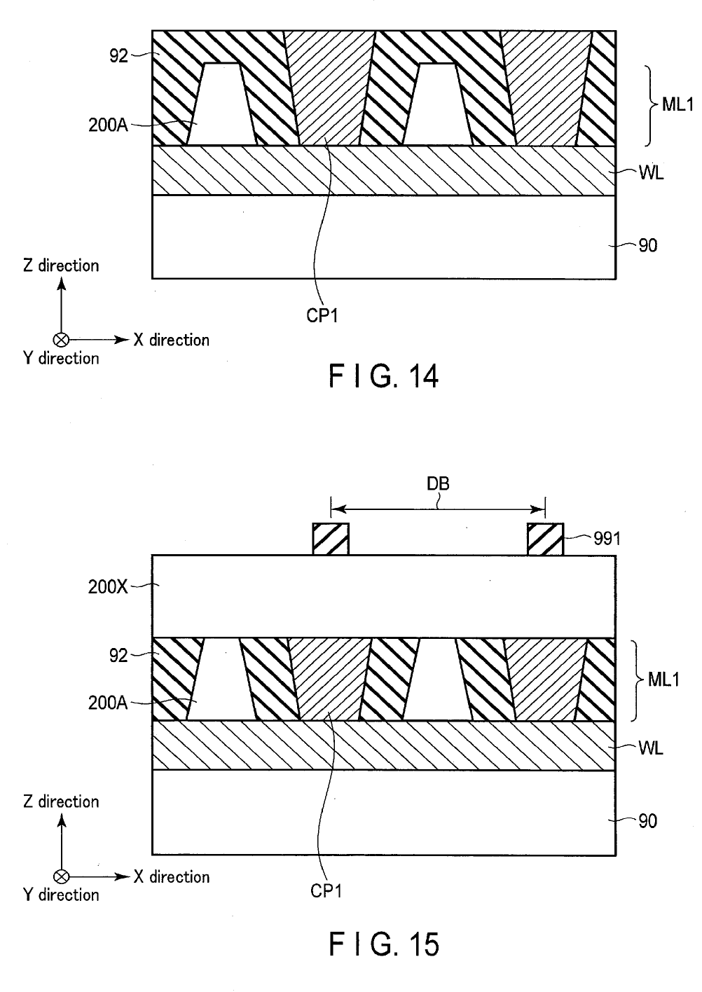

FIG. 14 is a cross-sectional view showing one step of the method of manufacturing the MRAM according to the present embodiment.

As illustrated in FIG. 14, the upper surface of the interlayer insulating film 92 is used as a stopper to apply a CMP process or an etch-back process to the conductor.

Thus, the contact plug CP1 is formed in a self-aligned manner in the interlayer insulating film 92. The contact plug CP1 has a reverse-tapered cross-sectional shape.

The MTJ element 200A and the contact plug CP1 are formed in the first array layer ML1.

FIG. 15 is a cross-sectional view showing one step of the method of manufacturing the MRAM according to the present embodiment.

As illustrated in FIG. 15, for example, the upper part (upper electrode) of the MTJ element 200A is used as a stopper to apply etching to the interlayer insulating film 92 and the contact plug CP1.

The upper part of the contact plug CP1 is positioned at the same height as the upper part of the MTJ element 200A. The interval between the MTJ element 200A and the contact plug CP1 has, for example, distance DA.

Thereafter, the stack 200X is formed on the MTJ element 200A, the contact plug CP1, and the interlayer insulating film 92. The stack 200X includes a plurality of layers to form MTJ elements in the second array layer. As described above, the stack 200X includes layers (materials) to form, from the substrate 90 side, a lower electrode, a reference layer, a tunnel barrier layer, a storage layer, and an upper electrode.

On the stack 200X, the mask layer 991 is formed in a formation region for the MTJ element of the second array layer. The mask layer 991 is arranged above the contact plug CP1 in the Z direction. The distance between adjacent mask layers 991 in the x direction (or the Y direction) is set to distance DB.

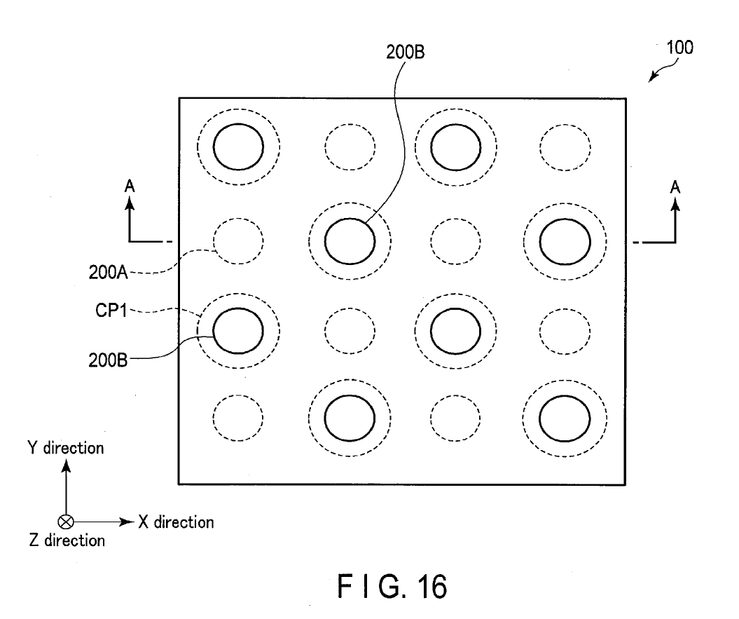

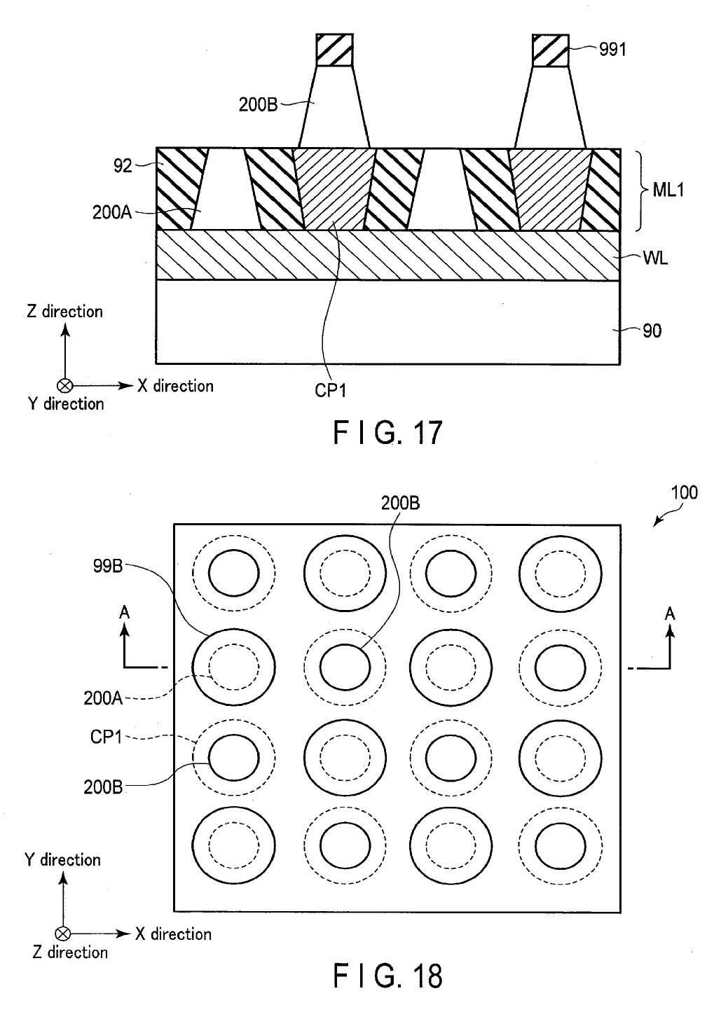

FIG. 16 is a plan view showing one step of the method of manufacturing the MRAM according to the present embodiment. FIG. 17 is a cross-sectional view taken along line A-A shown in FIG. 16 and showing one step of the method of manufacturing the MRAM according to the present embodiment.

As illustrated in FIG. 16 and FIG. 17, etching is applied to the stack on the first array layer ML1 by irradiation of ion beams from the oblique direction, as in the example of FIG. 10. The stack is removed from above the MTJ element 200A.

In this manner, the tapered MTJ element 200B is formed on the contact plug CP1.

The MTJ element 200B of the second array layer ML2 is formed on the first array layer ML1.

Similar to the step of forming the MTJ element 200A in the first array layer ML1 explained with reference to FIG. 9, since the relatively large space is ensured between two MTJ elements 200 in the second array layer ML2, irradiation of ion beams can be performed at a relatively large angle for the stack (MTJ element 200B).

FIG. 18 is a plan view showing one step of the method of manufacturing the MRAM according to the present embodiment. FIG. 19 is a cross-sectional view taken along line A-A shown in FIG. 18 and showing one step of the method of manufacturing the MRAM according to the present embodiment.

As illustrated in FIG. 18 and FIG. 19, the interlayer insulating film 93 is formed on the array layer ML1 in such a manner as to cover the MTJ element 200B.

An opening 99B is formed in a region between the MTJ elements 200B in the interlayer insulating film 93. The opening 99B is formed above the MTJ element 200A.

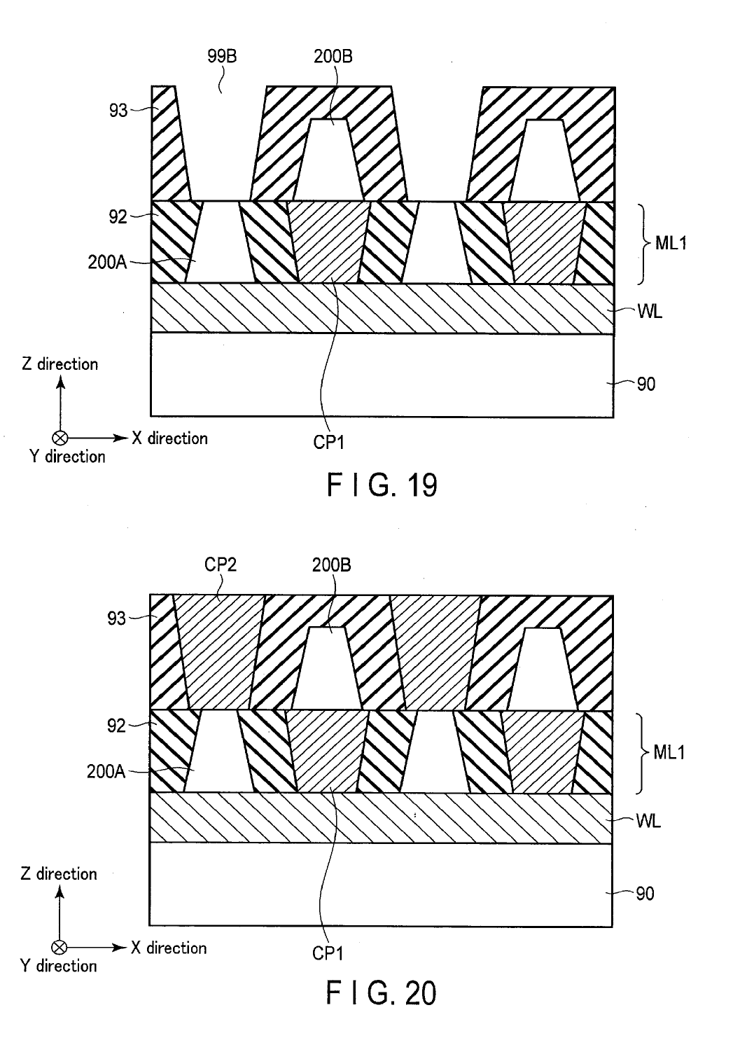

FIG. 20 is a cross-sectional view showing one step of the method of manufacturing the MRAM according to the present embodiment.

As illustrated in FIG. 20, by the step similar to that explained with reference to FIG. 13 and FIG. 14, the reverse-tapered contact plug CP2 is formed in a self-aligned manner in the opening of the interlayer insulating film 93.

In this manner, the contact plug CP2 is formed on the MTJ element 200A in the Z direction.

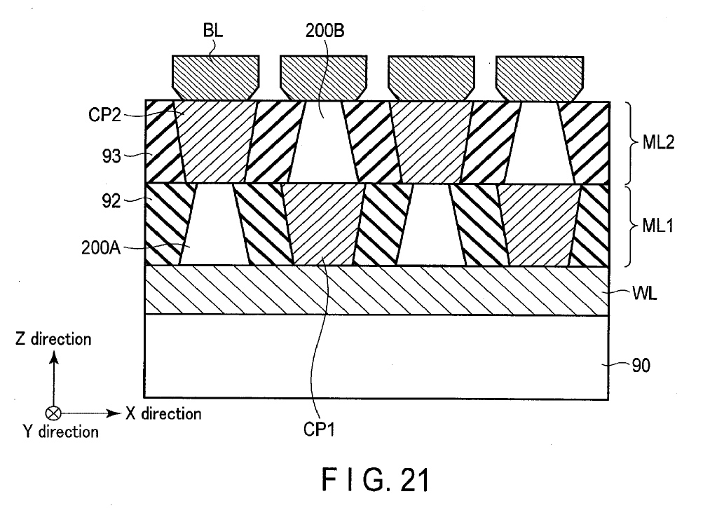

FIG. 21 is a cross-sectional view showing one step of the method of manufacturing the MRAM according to the present embodiment.

As illustrated in FIG. 21, by the step similar to that of FIG. 15, for example, the upper part (upper electrode) of the MTJ element 200B is used as a stopper to apply etching to the interlayer insulating film 93 and the contact plug CP2. The upper part of the contact plug CP2 is positioned at the same height as the upper part of the MTJ element 200B.

After etching is applied to the contact plug CP2 and the interlayer insulating film 93, the bit line BL is formed on the contact plug CP2 of the second array layer ML2 and the MTJ element 200A by a damascene process, for example.

The memory cell array of the MRAM according to the present embodiment is thus completed.

(c) Conclusion

In the memory device according to the present embodiment, the memory cell array includes the plurality of layers. Each of the layers is provided with the plurality of memory elements. Each of the layers is provided with the contact portions between the memory elements.

The memory element in the upper layer is stacked on the contact portion in the lower layer in the direction perpendicular to the surface of the substrate. The contact portion in the upper layer is stacked on the memory element in the lower layer in the direction perpendicular to the surface of the substrate. The memory element in the upper layer does not overlap with the memory element in the lower layer in a vertical direction.

In the present embodiment, in a given array layer, the tapered memory elements and the reverse-tapered contact portions are alternately arranged in the X direction and the Y direction. The density of the memory elements and the contact portions in the array layer can be high.

In the present embodiment, the layers including the plurality of memory elements are stacked in the Z direction. Thus, the storage density (the number of elements) per unit area is not lowered in the memory device according to the present embodiment.

Therefore, the memory device according to the present embodiment can provide a memory device including a memory cell array having high storage density.

The interval between MTJ elements disposed in the X direction or the Y direction can be relatively large in the plane parallel to the surface of the substrate.

Accordingly, the influence of the stray magnetic field of adjacent MTJ elements can be suppressed in the memory device according to the present embodiment.

The interval between memory elements in each array layer in the present embodiment can be large. Thus, in the present embodiment, when etching is applied to the memory element by irradiation of ion beams from the direction oblique to the surface of the substrate, the irradiation angle of the ion beams can be set to a relatively large angle.

In the present embodiment, it is therefore possible to lower the difficulty in processing the memory elements and to prevent the dispersant caused by etching from adhering to the memory elements again.

As a result, the memory device according to the present embodiment can realize a memory device including memory elements with high reliability (fewer defects).

When a dielectric breakdown of the tunnel barrier layer of the MTJ element occurs due to the supply of a large voltage/current, members of the MTJ element may be spread (scatter) by the impact of the breakdown.

In the present embodiment, the interval between adjacent MTJ elements is large and the contact plug is arranged between MTJ elements. Thus, in the present embodiment, it is possible to prevent the members spread by the dielectric breakdown of the MTJ elements from adhering to other MTJ elements or entering into other MTJ elements.

The thermal conductive property of the contact portion is higher than that of the memory element. Thus, in the present embodiment, since the contact portions are provided around the memory elements, it is possible to release heat of the memory elements in a relatively efficient manner.

If variable resistance elements other than MTJ elements are used as the memory elements in the memory device according to the present embodiment, similar effects can be obtained.

As described above, the memory device and the method of manufacturing the same according to the present embodiment can provide a memory device having high storage density and reliability.

### (2) Second Embodiment

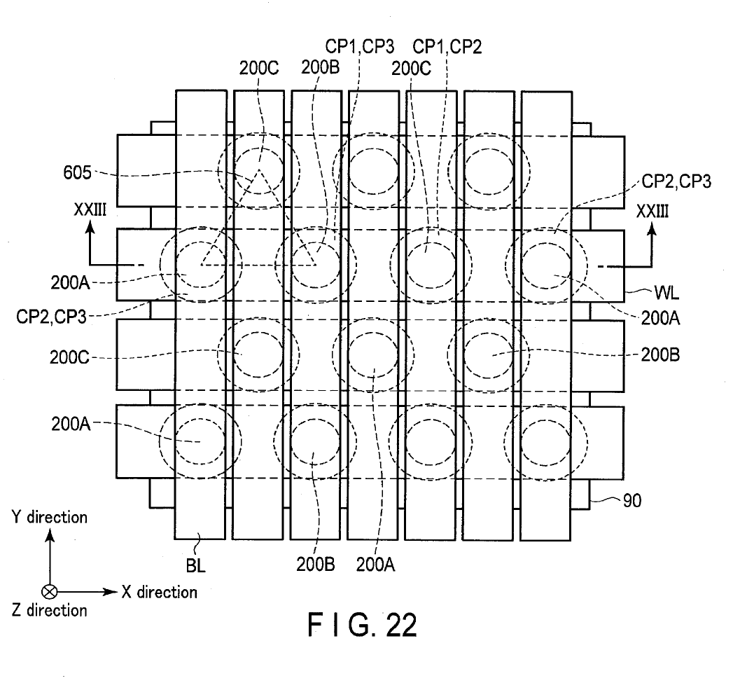

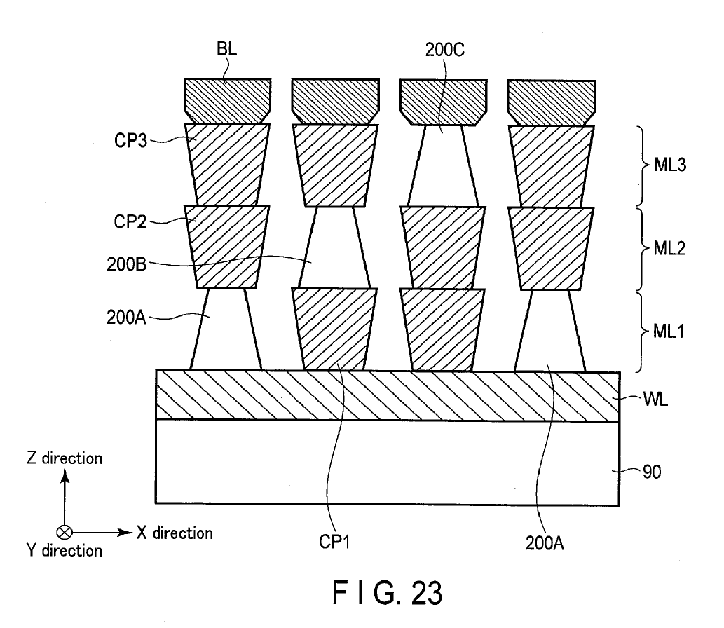

A memory device according to a second embodiment will be explained with reference to FIG. 22 and FIG. 23.

Three array layers may be stacked above the substrate in the memory cell array as in the present embodiment.

FIG. 22 is a plan view showing the configuration example of the memory cell array of the MRAM according to the present embodiment. FIG. 23 is a cross-sectional view taken along line XXIII-XXIII shown in FIG. 22. In FIG. 23, an illustration of the interlayer insulating film is not shown for the sake of clarity of the figure.

As illustrated in FIG. 22, when the substrate 90 is viewed in the Z direction, three memory elements (for example, MTJ elements 200) are arranged in the X-Y plane in a unit of a regular triangle 605.

The MTJ elements 200 are arranged at the respective vertices of the regular triangle.

In the three-layer memory cell array, the MTJ elements 200 on the vertices (corners) of the regular triangle are provided on layers (array layers) ML different from each other.

For example, MTJ elements arranged in the Y direction are provided in the same array layer ML.

As illustrated in FIG. 23, three array layers ML1, ML2, and ML3 are stacked above the substrate 90 in the Z direction.

The memory elements (for example, MTJ elements) 200A, 200B, and 200C adjacent in the X direction are provided in array layers different from each other.

In the first array layer ML1, the memory element 200A is provided on the word line WL. Two contact plugs CP2 and CP3 are provided between the memory element 200A and the bit line BL.

In the first array layer ML1, the memory element 200A is adjacent to the contact plug CP1 in the X direction and the Y direction.

In the second array layer ML2, the memory element 200B is provided between the contact plug CP1 and the contact plug CP3 in the z direction.

In the second array layer ML2, the memory element 200B is adjacent to the contact plug CP2 in the X direction and the Y direction.

In the third array layer ML3, the memory element 200C is provided between the bit line BL and the contact plug CP2 in the Z direction. Two contact plugs CP1 and CP2 are provided between the memory element 200C and the word line WL.

In the third array layer ML3, the memory element 200C is adjacent to the contact plug CP3 in the X direction and the Y direction.

As in the present embodiment, even when three array layers are stacked on the substrate, it is possible to comparatively lower the difficulty in processing the elements and realize a memory device having high reliability and high storage density.

### (3) Third Embodiment

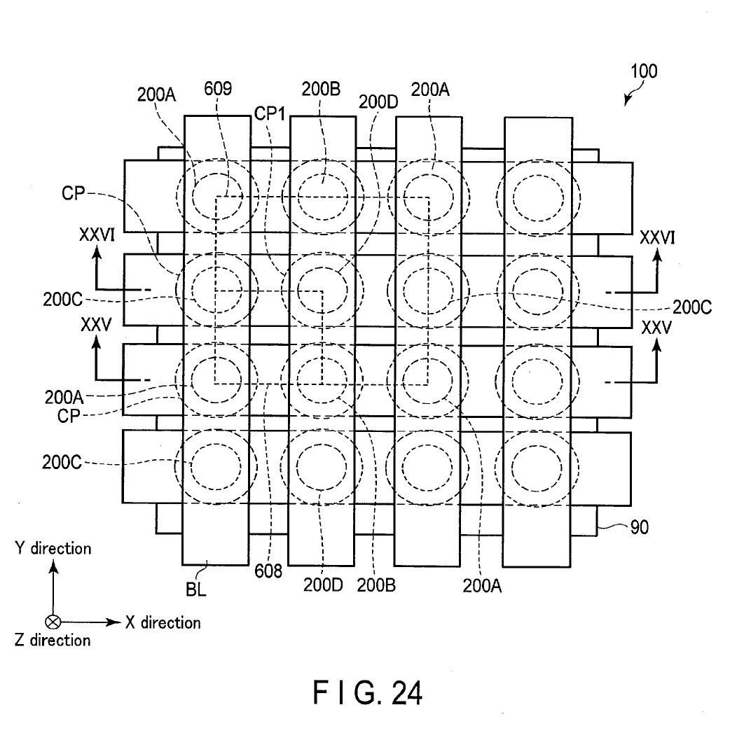

A memory device according to a third embodiment will be explained with reference to FIG. 24 to FIG. 26.

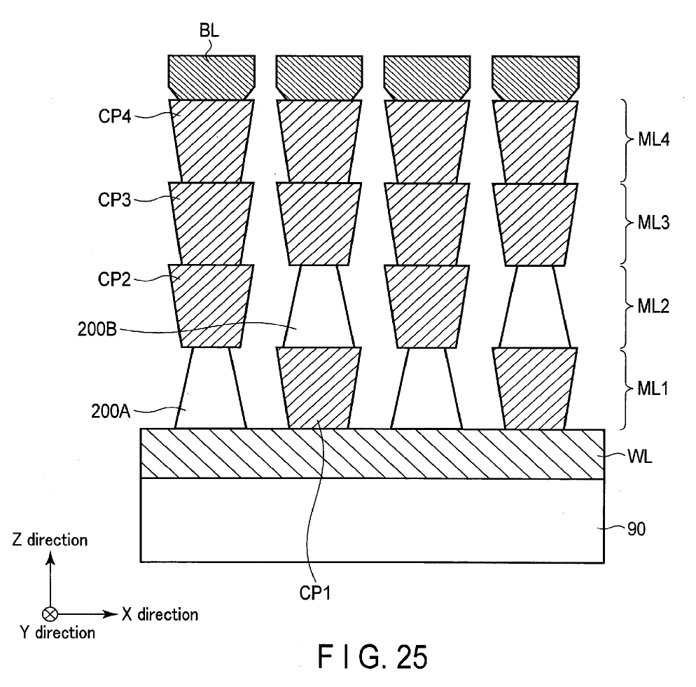

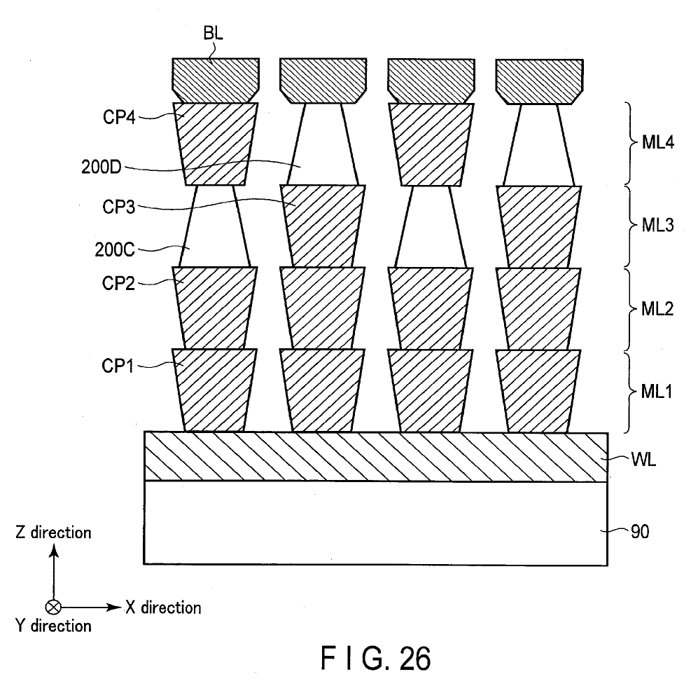

FIG. 24 is a plan view showing the configuration example of the memory cell array of the MRAM according to the present embodiment. FIG. 25 is a cross-sectional view taken along line XXV-XXV shown in FIG. 24. FIG. 26 is a cross-sectional view taken along line XXVI-XXVI shown in FIG. 24. In FIG. 25 and FIG. 26, an illustration of the interlayer insulating film is not shown for the sake of clarity of the figures.

As illustrated in FIG. 24 to FIG. 26, in the memory cell array 100, four array layers ML1, ML2, ML3, and ML4 may be stacked above the substrate 90 in the Z direction.

In the memory cell array 100 having a four-layer structure, for example, in a 3×3 quadrangle in the X-Y plane, memory elements (for example, MTJ elements) 200 at the vertices (corners) of the quadrangle are memory elements in the same array layer. In the example of FIG. 24, the memory elements 200A in the first array layer ML1 are arranged on vertices of a 3×3 quadrangle 609.

In the 3×3 quadrangle 609 in the X-Y plane, the memory elements on the sides facing each other are memory elements in the same array layers. In the example of FIG. 24, the MTJ elements 200B of the second array layer ML2 and the MTJ elements 200C of the third array layer ML3 are arranged on sides of the 3×3 quadrangle 609.

In the 3×3 quadrangle 609, the array layer having the memory element at the center of the 3×3 quadrangle is different from the array layer having the memory elements on the vertices of the quadrangle 609 and the array layer having the memory elements on the sides. In the example of FIG. 24, the MTJ element 200D of the fourth array layer ML4 is arranged at the center of the 3×3 quadrangle 609.

In the example of FIG. 24, in a 2×2 quadrangle 608 in the X-Y plane, the memory elements 200 at the vertices of the quadrangle 608 are memory elements in array layers ML different from each other.

The plurality of MTJ elements 200 disposed on the same linear line in the X direction (or the Y direction) viewed in the Z direction are memory elements respectively provided in two array layers ML. In the X-Y plane, the memory elements 200 disposed in the oblique direction are memory elements respectively provided in two array layers ML.

For example, as illustrated in FIG. 25, the memory element 200A in the first array layer ML1 and the memory element 200B in the second array layer ML2 are alternately arranged in the X direction.

The contact plugs CP2, CP3, and CP4 of the respective array layers ML2, ML3, and ML4 are provided on the memory element 200A. The memory element 200B is provided on the contact plug CP1. The contact plugs CP3 and CP4 are provided on the memory element 200B.

As illustrated in FIG. 26, in the arrangement adjacent in the Y direction to the arrangement consisting of the memory element 200A and the memory element 200B, the MTJ element 200C in the third array layer ML3 and the MTJ element 200D in the fourth array layer ML4 are alternately arranged in the X direction.

The memory element 200C is provided above the stacked contact plugs CP1 and CP2. The contact plug CP4 is provided on the memory element 200C. The memory element 200D is provided on the stacked contact plugs CP1, CP2, and CP3. The bit lines BL are provided on the memory element 200D and the contact plug CP4.

The MTJ element 200A in the first array layer ML1 and the MTJ element 200C in the third array layer ML3 are alternately arranged in the Y direction.

In the arrangement pattern in the Y direction adjacent in the X direction to the arrangement pattern (column) of the MTJ elements 200A and 200C of the first and third array layers, the MTJ element 200B in the second array layer ML2 and the MTJ element 200D in the fourth array layer ML4 are alternately arranged.

Like the memory according to the present embodiment, even when the memory cell array has a stack structure of four array layers, advantageous effects substantially similar to those of the first and second embodiments can be obtained.

### (4) Fourth Embodiment

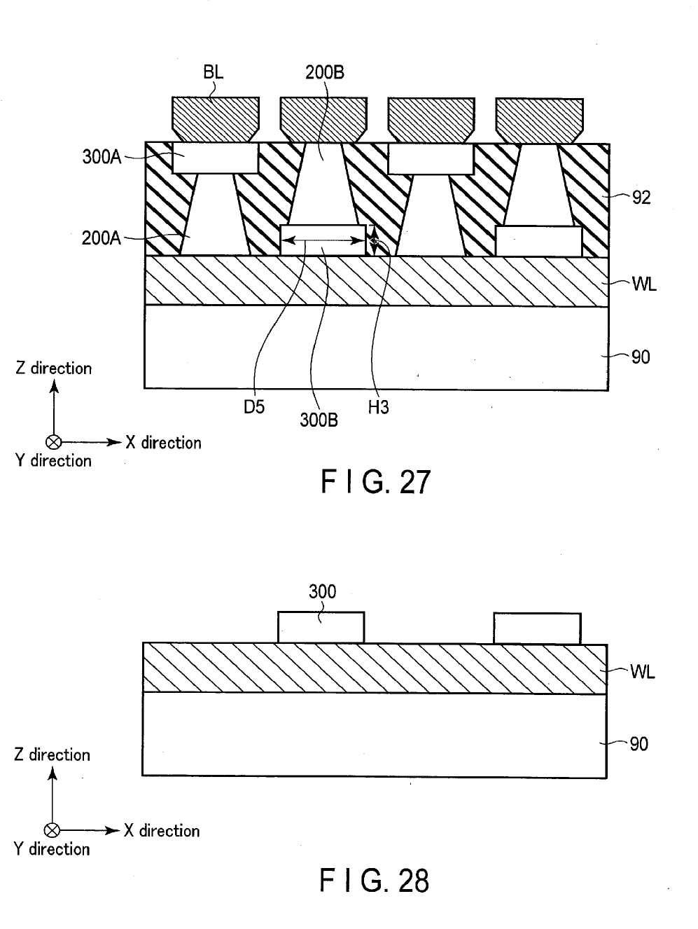

A memory device and a method of manufacturing the memory device according to a fourth embodiment will be explained with reference to FIG. 27 to FIG. 31.

FIG. 27 is a cross-sectional view showing the configuration example of the memory cell array of the MRAM according to the present embodiment.

As illustrated in FIG. 27, a selector element 300 may be provided in the memory cell MC.

The selector element 300 is one element selected from a diode, a switching element (for example, a variable resistance element), a capacitor, and the like. The selector element 300 is, for example, an element including a GeTe layer.

The selector element 300 can suppress noise between a selected cell and a non-selected cell (for example, a current flowing between memory cells) during operation of the memory device (for example, write operation and read operation).

A first MTJ element 200A and a second MTJ element 200B are alternately arranged in the X direction (or the Y direction).

The first MTJ element 200A is provided on the word line WL. A first selector element 300A is provided on the first MTJ element 200A. A bit line BL is provided on the first selector element 300A.

The second MTJ element 200B is provided on a second selector element 300B. The second selector element 300B is provided between the second MTJ element 200B and the word line WL. The second MTJ element 200B is provided between the bit line BL and the second selector element 300B.

In the present embodiment, two types of memory cells MC, in which the stacking order of the MTJ element 200 and the selector element 300 is opposite to each other, are alternately arranged in the X direction and the Y direction.

Dimension D5 of the selector element 300 in the direction parallel to the surface of the substrate is equal to or larger than dimension D2 of the MTJ element 200. Dimension H3 of the selector element 300 in the direction perpendicular to the surface of the substrate is smaller than dimension H1 of the MTJ element 200.

The cross-sectional shape of the selector element 300 may be tapered. In the tapered selector element 300, the dimension at the upper part (the portion at the bit line side) of the selector element 300 is smaller than the dimension at the lower part (the portion at the word line side) of the selector element 300. The cross-sectional shape of the selector element 300 may be reverse-tapered. In the reverse-tapered selector element 300, the dimension at the upper part of the selector element 300 is larger than the dimension at the lower part of the selector element 300.

A method of manufacturing the memory device according to the present embodiment will be explained with reference to FIG. 28 to FIG. 31.

Each of FIG. 28 to FIG. 31 is a process cross-sectional view showing one step of the method of manufacturing the memory device according to the present embodiment.

As illustrated in FIG. 28, the selector element 300B is formed on the word line WL in a formation region of the second memory cell.

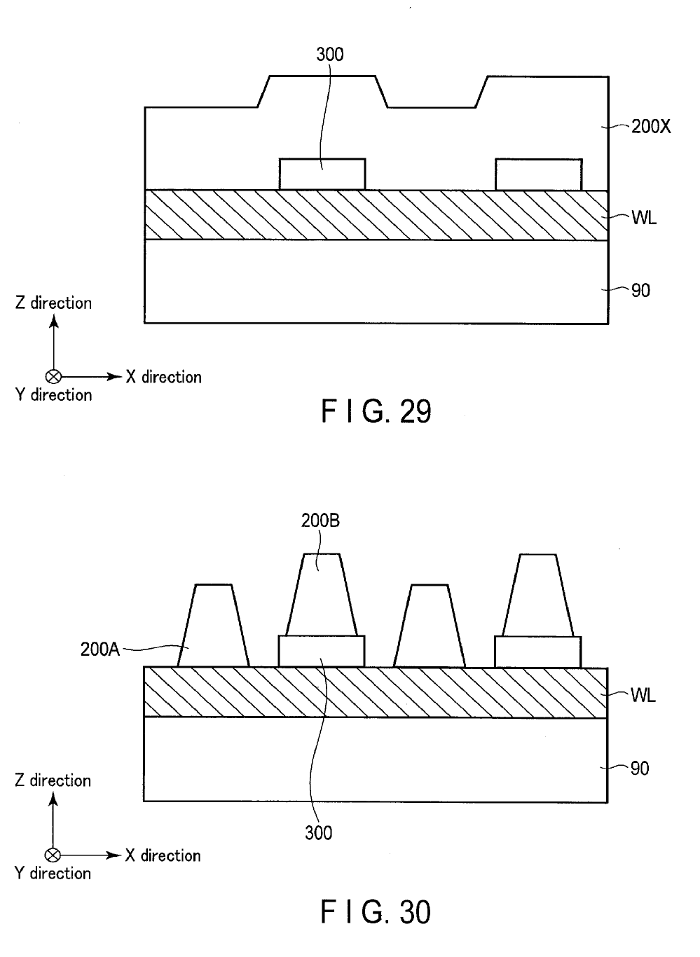

As illustrated in FIG. 29, the stack 200X to form memory elements (for example, MTJ elements) is formed above the substrate 90. The stack 200X is formed on the word line WL and the selector element 300B.

As illustrated in FIG. 30, for example, the memory elements 200A and 200B are formed by irradiation of ion beams from the oblique direction.

The tapered memory element 200A is formed on the word line WL. The tapered memory element 200B is formed on the selector element 300B.

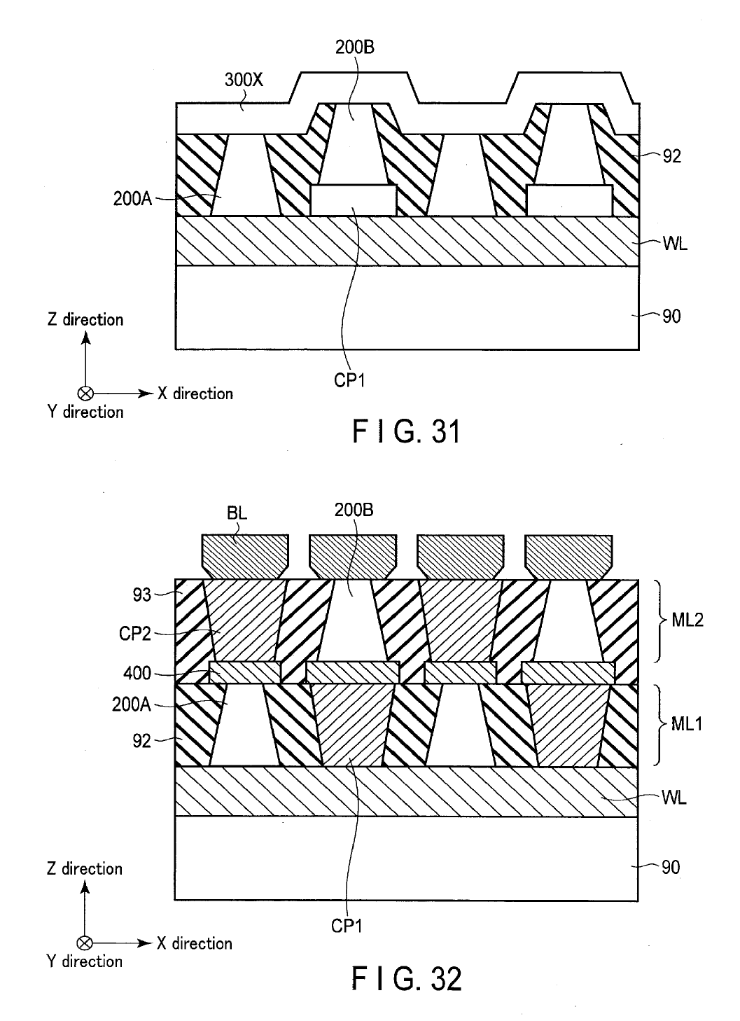

As illustrated in FIG. 31, an interlayer insulating film 92 is formed on the memory elements 200A and 200B. Thereafter, etching is applied to the formation region of the first memory cell in such a manner that an upper part of the memory element 200A is exposed.

A member (for example, a stack) 300X to form the selector element is formed on the interlayer insulating film 92 and the memory element 200A.

Thereafter, etching is applied to the member 300X in such a manner that the selector element having a predetermined shape is formed.

In this manner, the memory cell array of the configuration of FIG. 27 is formed.

The selector element may have a relatively large area for stabilization of operation of the element.

In the present embodiment, the memory element has a tapered cross-sectional shape. In the present embodiment, the memory cells adjacent in the X direction or the Y direction are formed in such a manner that the selector elements alternate in the Z direction.

Therefore, in the memory device according to the present embodiment, the memory cells including the selector elements can be arranged with high density in the memory cell array.

Furthermore, when the selector elements are provided in the memory cell as in the present embodiment, reliability of the operation of the memory device according to the present embodiment can be improved.

### (5) Fifth Embodiment

A memory device and a method of manufacturing the memory device according to a fifth embodiment will be explained with reference to FIG. 32 to FIG. 34.

FIG. 32 is a cross-sectional view showing the configuration example of the memory cell array of the MRAM according to the present embodiment.

As illustrated in FIG. 32, a buffer layer 400 may be provided between a first array layer ML1 and a second array layer ML2.

The buffer layer 400 is provided between a memory element (for example, MTJ element) 200 and a contact plug CP.

The buffer layer 400 may be provided between the selector element 300 and the memory element 200 of FIG. 27.

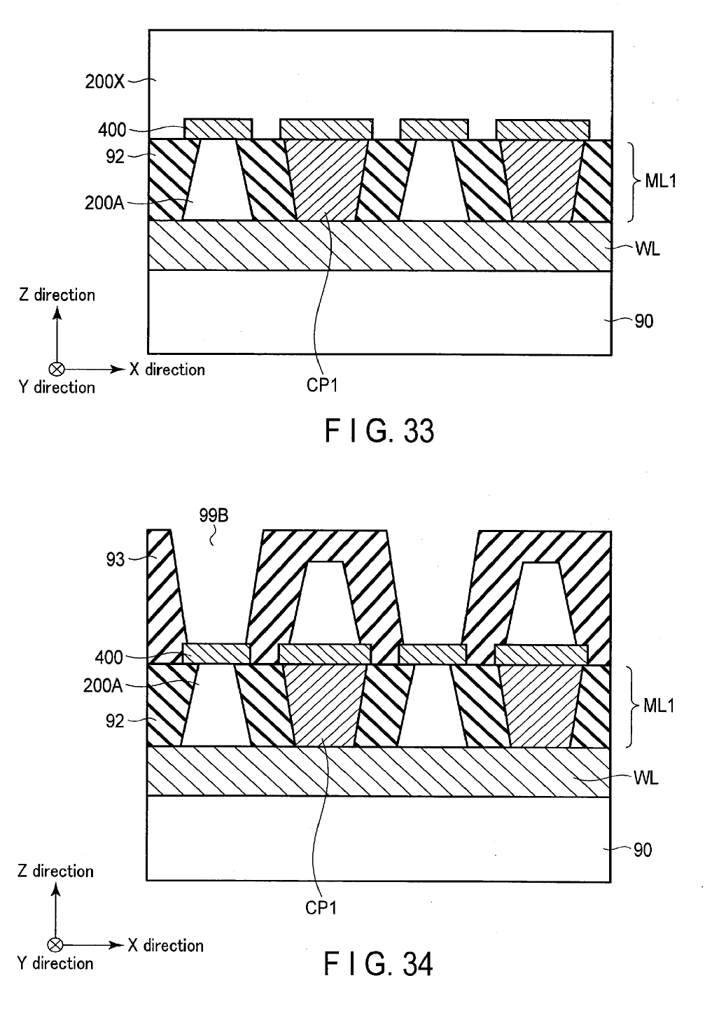

A method of manufacturing the memory device according to the present embodiment will be explained with reference to FIG. 33 and FIG. 34.

Each of FIG. 33 and FIG. 34 is a process cross-sectional view showing one step of the method of manufacturing the memory device (for example, an MRAM) according to the present embodiment.

As illustrated in FIG. 33, after the first array layer ML1 is formed, the buffer layer 400 is formed on the MTJ element 200A and the contact plug CP1 by the well-known film forming technique.

A stack 200X is formed on the buffer layer 400 and the interlayer insulating film 92.

As illustrated in FIG. 34, the MTJ element 200B is formed above the contact plug CP1 via the buffer layer 400.

After the MTJ element 200B in the second array layer is formed, the interlayer insulating film 93 is formed on the first array layer ML1.

An opening 99B is formed above the first MTJ element 200A.

The buffer layer 400 is formed on the MTJ element 200A at the time of forming the opening 99B. The buffer layer 400 is used as a stopper in etching for forming the opening 99B. The upper surface of the buffer layer 400 is exposed by etching.

Accordingly, in the present embodiment, it is relatively easy to form an opening at a region above the MTJ element 200A.

Because of the buffer layer 400, the MTJ element 200A is not directly subject to etching conditions for forming the opening 99B.

Thus, in the present embodiment, it is possible to reduce damage to MTJ elements by etching for forming the opening 99B.

Thereafter, the contact plug CP2 in the second array layer ML2 and the bit line BL are sequentially formed, as in the example described above.

As described above, according to the memory device and the manufacturing method thereof according to the present embodiment, difficulty in forming the memory device can be lowered and deterioration of element characteristics caused by manufacturing processes can be suppressed.

### (6) Sixth Embodiment

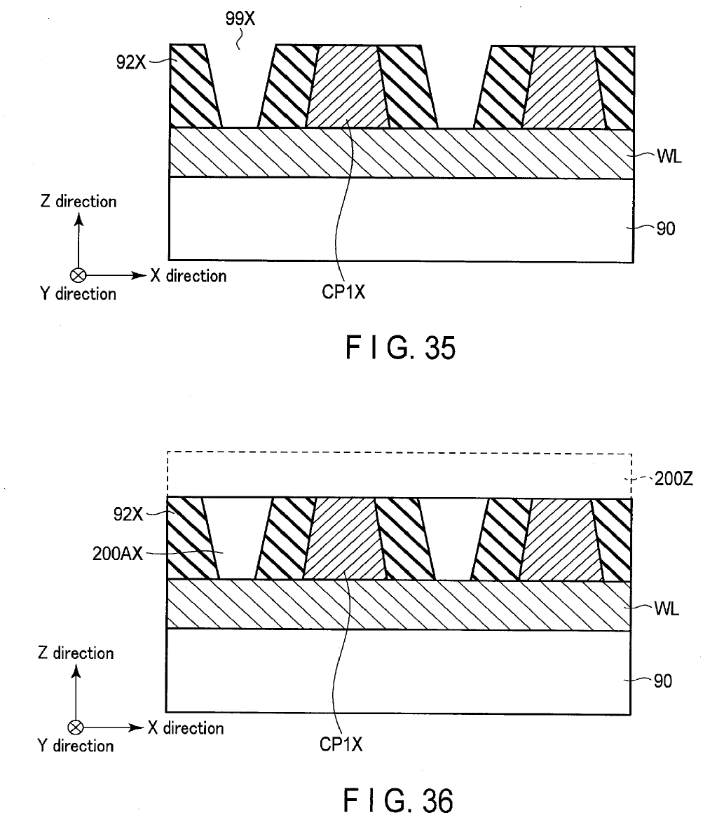

A memory device and a method of manufacturing the memory device according to a sixth embodiment will be explained with reference to FIG. 35 to FIG. 38.

Memory elements (for example, MTJ elements) may be formed by a damascene process as the memory device according to the present embodiment.

FIG. 35 to FIG. 38 are process cross-sectional views showing one step of the method of manufacturing the memory device according to the present embodiment.

As illustrated in FIG. 35, after a contact plug CP1X is formed on a word line WL, an interlayer insulating film 92X is formed on the substrate 90 in such a manner as to cover the contact plug CP1X. For example, the contact plug CP1X has a tapered cross-sectional shape. The cross-sectional shape of the contact plug CP1X may be quadrangular (for example, rectangular).

In a formation region of the memory element, a reverse-tapered opening 99X is formed in the interlayer insulating film 92X.

As illustrated in FIG. 36, a stack (member) 200Z to form memory elements is formed on the interlayer insulating film 92X so as to fill in the opening 99X. The upper surface of the interlayer insulating film 92X is used as a stopper to apply an etch-back process or a CMP process to the stack 200Z. The stack 200Z is removed from above the upper surface of the interlayer insulating film 92X and remains in a self-aligned manner in the opening.

In this manner, a memory element 200AX is formed in the opening of the interlayer insulating film 92X. For example, the memory element 200AX has a reverse-tapered cross-sectional shape.

Thereafter, etching may be applied to end portions (side surfaces) of the memory element 200AX in the opening 99X. In this case, the memory element 200AX has a quadrangular (for example, rectangular) cross-sectional shape.

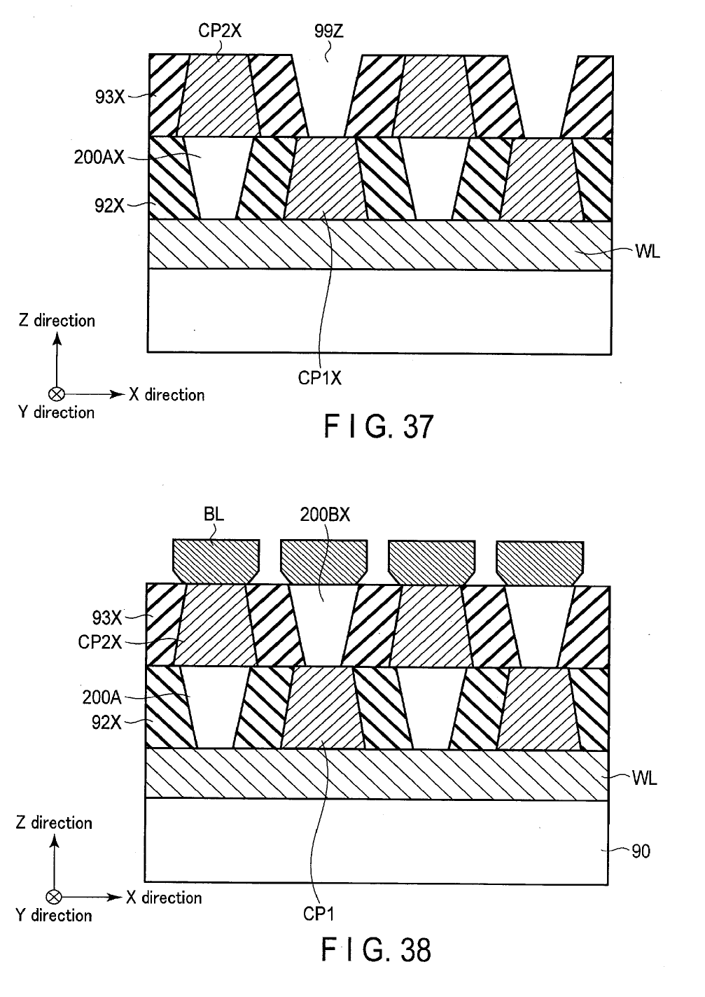

As illustrated in FIG. 37, a tapered contact plug CP2X is formed on the memory element 200AX.

A second interlayer insulating film 93X is formed on the first interlayer insulating film 92X so as to cover the contact plug CP2X.

In a formation region of the second memory element, an opening 99Z is formed above the contact plug CP1X.

Thereafter, the stack to form memory elements is filled in the opening 99Z in a self-aligned manner by the step similar to that of FIG. 36.

Thus, a reverse-tapered memory element 200BX is formed on the contact plug CP1X as illustrated in FIG. 38.

Thereafter, bit lines BL are formed on the memory element 200BX and the contact plug CP2X.

As described above, the memory element can be formed by a damascene process in the present embodiment.

### (7) Modification

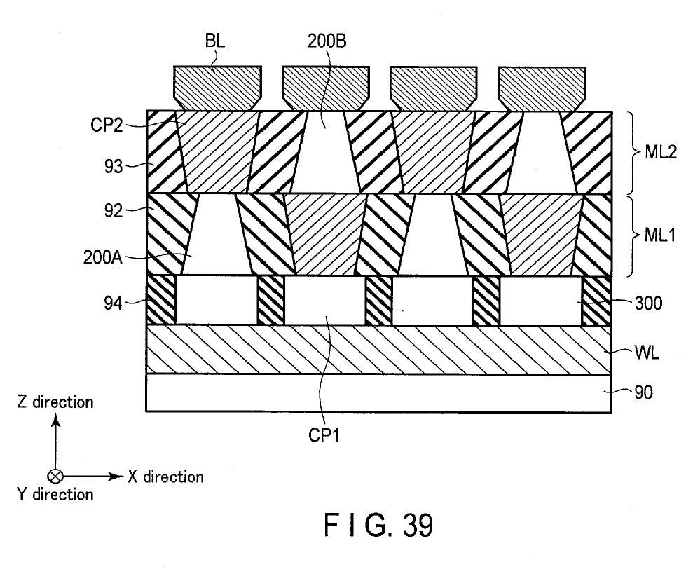

A modification of the memory device according to the embodiment will be described with reference to FIG. 39.

FIG. 39 is a cross-sectional view showing a modification of the memory cell array of the memory device of the embodiment.

As illustrated in FIG. 39, the selector element 300 is provided, for example, between the word line WL and the memory element 200A, and between the word line WL and the contact plug CP1, in the interlayer insulating film 94.

In the example of FIG. 39, the selector element 300 is formed after the word line WL is formed and before the stack 200X is formed in the manufacturing process of FIG. 8.

For example, a layer (a single layer film or a stack layer film) to form the selector element 300 is deposited on the word line WL. Etching is applied to the layer on the word line to have a predetermined shape. Thereby, the selector element 300 is formed on the word line WL.

The stack to form memory elements is deposited on the formed selector element 300. Thereafter, the manufacturing steps of FIG. 9 to FIG. 21 are performed.

The selector element 300 may be connected between the memory element 200 and the bit line BL. In this case, the selector element 300 is provided between the bit line BL and the memory element 200B, and between the bit line BL and the contact plug CP2.

### (8) Others

While certain embodiments have been described, these embodiments have been presented by way of example only, and are not intended to limit the scope of the inventions.

Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first memory element arranged above a substrate;
a first contact portion adjacent to the first memory element in a first direction parallel to a surface of the substrate;
a second contact portion arranged above the first memory element in a second direction perpendicular to the surface of the substrate; and
a second memory element arranged above the first contact portion in the second direction,
wherein
first dimensions at upper parts of the first and second memory elements are smaller than second dimensions at lower parts of the first and second memory elements, and
third dimensions at upper parts of the first and second contact portions are larger than fourth dimensions at lower parts of the first and second contact portions.

2. The device according to claim 1, further comprising:
a first buffer layer arranged between the first memory element and the second contact portion; and
a second buffer layer arranged between the first contact portion and the second memory element.

3. The device according to claim 1, further comprising:
a third contact portion adjacent to the first memory element in a third direction parallel to the surface of the substrate and intersecting with the first direction;
a third memory element arranged above the third contact portion in the second direction and adjacent to the second contact portion in the third direction;
a fourth memory element adjacent to the first contact portion in the third direction; and
a fourth contact portion arranged above the fourth memory element in the second direction and adjacent to the second memory element in the third direction.

4. The device according to claim 3, wherein
upper parts of the third and fourth memory elements have the first dimensions, and lower parts of the third and fourth memory elements have the second dimensions, and
upper parts of the third and fourth contact portions have the third dimensions, and lower parts of the third and fourth contact portions have the fourth dimensions.

5. The device according to claim 1, wherein
the second dimensions are not more than the third dimensions.

6. The device according to claim 1, wherein
a fifth dimension of the first memory element in the second direction is equal to a sixth dimension of the first contact portion in the second direction.

7. The device according to claim 1, wherein
the first and second memory elements are magnetoresistive effect elements.

8. The device according to claim 1, further comprising:
a first selector element arranged between the first memory element and the substrate; and
a second selector element arranged between the first contact portion and the substrate.

9. The device according to claim 1, further comprising:
a first word line arranged below the first memory element and the first contact portion in the second direction and extending in the first direction;
a first bit line arranged above the second contact portion in the second direction and extending in a third direction, the third direction parallel to the surface of the substrate and intersecting with the first direction; and
a second bit line above the second memory element in the second direction and extending in the third direction.

10. The device according to claim 1, wherein
the first, second, third, and fourth dimensions are dimensions in the first direction.

11. A memory device comprising:
a first memory element arranged above a substrate;
a first selector element adjacent to the first memory element in a first direction parallel to a surface of the substrate;
a second selector element arranged above the first memory element in a second direction perpendicular to the surface of the substrate; and
a second memory element arranged above the first selector element in the second direction,
wherein
first dimensions at upper parts of the first and second memory elements are smaller than second dimensions at lower parts of the first and second memory elements.

12. The device according to claim 11, further comprising:
a third selector element adjacent to the first memory element in a third direction parallel to the surface of the substrate and intersecting with the first direction;
a third memory element arranged above the third selector element in the second direction and adjacent to the second selector element in the third direction;
a fourth memory element adjacent to the first selector element in the third direction; and
a fourth selector element arranged above the fourth memory element in the second direction and adjacent to the second memory element in the third direction.

13. The device according to claim 12, wherein
upper parts of the third and fourth memory elements have the first dimensions, and lower parts of the third and fourth memory elements have the second dimensions.

14. The device according to claim 11, wherein
third dimensions of the first selector element in the second direction are smaller than fourth dimensions of the first memory element in the second direction.

15. The device according to claim 11, wherein
fifth dimensions of the first and second selector elements in the first direction are not less than the second dimensions.

16. The device according to claim 11, wherein
the first and second memory elements are magnetoresistive effect elements.

17. The device according to claim 11, wherein
each of the first and second selector elements is an element selected from a diode, a capacitor, and variable resistance element.

18. The device according to claim 11, further comprising:
a first word line arranged below the first memory element and the first selector element in the second direction and extending in the first direction;
a first bit line arranged above the second selector element in the second direction and extending in a third direction, the third direction parallel to the surface of the substrate and intersecting with the first direction; and
a second bit line above the second memory element in the second direction and extending in the third direction.

19. The device according to claim 11, wherein
the first and second dimensions are dimensions in the first direction.
